(19) United States
(12) Patent Application Publication
(10) Pub. No.: US 2019/0057792 A1
(43) Pub. Date: Feb. 21, 2019

(54) ELECTRICALLY CONDUCTIVE COMPOSITION AND APPLICATIONS FOR SAID COMPOSITION

(71) Applicant: Henkel AG & Co. KGaA, Duesseldorf (DE)

(72) Inventors: Michel Ruyters, Tessenderlo (BE); Anja Henckens, Zonhoven (BE); Hui-Wang Cui, Shanghai (CN); Jing Yang, Shanghai (CN); Gunther Dreezen, Balen-Olmen (BE)

(21) Appl. No.: 16/108,392

(22) Filed: Aug. 22, 2018

Related U.S. Application Data
(63) Continuation of application No. PCT/CN2016/074287, filed on Feb. 22, 2016.

(51) Int. Cl. H01B 1/22; H01L 31/0747; H01L 31/18; H01L 31/0224

(52) U.S. Cl. CPC H01B 1/22; H01L 31/0747; C08L 63/00; H01L 31/022425; H01L 31/022466; H01L 31/182

(57) ABSTRACT

The present invention is directed to an electrically conductive composition for use in the preparation of an electrically conductive network, said composition comprising, based on the total weight of the composition: a) from 75 to 98 wt. % of a silver powder having a tap density of at least 4.0 g/cm³ and a specific surface area of less than 1.5 m²/g; b) from 1 to 10 wt. % of a binder resin; c) from 0 to 5 wt. % of a hardener; and, d) from 0 to 10 wt. % of solvent, wherein said composition is characterized in that, when heated to a temperature at which the silver powder starts to sinter, the binder resin is not yet fully cured or fully solidified.

### FIELD OF THE INVENTION

The present invention is concerned with an electrically conductive composition which may be used in the preparation of an electrically conductive network. More particularly, it is concerned with an electrically conductive composition comprising sinterable silver particles dispersed in a binder resin, which binder resin is not yet in a fully cured or fully solidified state when the composition is heated to a temperature at which the silver particles start to sinter.

### BACKGROUND TO THE INVENTION

It is widely accepted that solar power represents an important alternative energy source which can both contribute to the meeting of increasing global energy demand and mitigate the deleterious effects of fossil fuels and nuclear power on earth ecology. However, the future expansion of solar power generation will be linked to its competitiveness relative to conventional power generation methods and this, in turn, will depend on technological advances that can lead to higher efficiency, reliability and lower cost of the photovoltaic (PV) solar cells used to convert sunlight into electricity.

The efficiency and reliability of solar cells are largely affected by the nature and quality of the contact metallization—often termed the “electrode” —which provides electrically conducting paths on the surface of the cell to collect and transfer photo-converted charges to an external circuit, thus generating useful electrical energy.

At present, crystalline solar cells (c-Si), having a thickness of the order of 20-300 microns, still represent an important technology and are fabricated using either mono-crystalline silicon or polycrystalline silicon as substrates. These substrates are commonly modified with a dopant, being by convention: positively or p-doped silicon, where holes are the majority electrical carriers; and, negatively or n-doped silicon, where electrons are the majority electrical carrier. Further, the surface of the substrate, or wafer, which is intended to face incident light is designated as the front surface and the surface opposite the front surface is referred to as the back surface. Crucially, the photovoltaic cell further comprises a p-n junction, usually formed by further p-doping or n-doping a thin emitter layer at the front surface of the silicon substrate. The bulk silicon—or absorber layer—is usually covered by a dielectric film that acts as an anti-reflective coating.

Electrodes are formed on the front and back surfaces of such crystalline silicon PV devices, whereby those electrodes disposed on the front surface are deposited thereon in arrays. It is desirable that the electrodes on both the front and back side of the device have both high conductivity and low contact resistance. For standard crystalline silicon PV devices, the metallization pastes used are typically fired at high temperature—over 800° C., for example—to form the electrodes. For heterojunction crystalline silicon PV devices, much lower temperatures—around 200° C., for example—are used in order to prevent damage to films underneath, such as the doped a-Si:H film that is sensitive to high annealing temperatures.

It will be recognized that the industrial production of thin film solar cell technologies is also significant and includes production of thin film, amorphous (a-Si) type solar cells, silicon tandem solar cells (a-Si/μ-Si), and polycrystalline compound solar cells based on, for instance, cadmium-telluride (CdTe), copper-indium-selenide (CuInSe₂, or CIS) and copper indium gallium selenide (CIGS). The photoelectric conversion layer in thin film solar cells contains at least one p-i-n junction and the stack of the active layer is normally of the order of microns thick. As a consequence, the sheet resistance of the active layer in thin film solar cells is relatively high and this can retard lateral charge transfer during charge collection by the front electrode. However, it is generally ineffective to compensate for this effect only by increasing the density of grid lines on the front face of the solar cell because this increases the shading of the photovoltaic junction and thereby reduces cell output.

To effectively mitigate this drawback of thin film active layers, the front electrode of thin film solar cells is now generally comprised of a transparent conductive oxide (TCO) which enables incident light to reach the light absorbing material and serves as an ohmic contact to collect electrical charges converted there from the light radiation. The TCO also acts as an anti-reflective coating (ARC) layer. Since the resistance of TCO is intrinsically high, metal grid lines must be added on the TCO surface to further assist in charge collecting. And an intimate contact between metal in the grid lines and TCO surface is highly desired to ensure the efficiency of the charge collecting.

The present invention is, in particular, concerned with the contact metallization within inter alia heterojunction crystalline silicon, thin film solar cells such as Cl(G)S, CdTe and α-Si/μ-Si, amorphous silicon and bulk heterojunction solar cells, whereby the electrode array is formed by deposition of polymeric films on the substrate surface using inks, pastes or other compositions which also comprise metal particles. The compositions are deposited—by printing for instance—as a network and then the constituent polymeric binder is cured or dried at a relatively low temperature, such as below 250° C. After curing, the metal particles are physically connected to each other and fixed by a polymer matrix, thus forming a conductive film. The polymer resins or binders also provide adhesion to TCO layers, when present. However, it is recognized that the resistivity of such types of collecting electrodes is typically significantly higher than electrodes made by metal thick film deposition; this leads to an increase in Joule loss and concomitantly a reduction of conversion efficiency. Moreover, the solderability of the formed electrode is normally poor due to insufficient and embedded metal particles. And silver migration can be problematic where this metal or alloys thereof are employed as conductive fillers.

EP 2 455 947 B1 (Cheil Industries) describes a conductive paste composition which can be used in forming a low temperature-type electrode disposed on a transparent conductive oxide. The conductive paste composition comprises a conductive powder, a binder resin and a solvent wherein the conductive powder comprises a flake type powder having an average particle diameter (D50) of ≥1.2 μm to ≥3.0 μm and a spherical powder having an average particle diameter (D50) of ≥0.2 μm to ≥2.0 μm in a weight ratio of 1:0.4 to 1:2, and the conductive powder and the binder resin are present in a weight ratio of 1:0.04 to 1:0.08.

JP 2013 214733 (Namics Corporation) discloses a thermally conductive paste comprising from 2 to 7 parts by weight of a thermosetting resin binder and 100 parts by weight of sinterable silver particles having an average particle diameter of from 1 to 500 nm and wherein said particles and resin are dispersed in the organic medium. A cured film is formed from said composition by heating for 1 hour at 200° C.

US 2011/0111404 A1 (Hwang et al.) describes a thermosetting electrode paste sinterable at a low temperature, which paste comprises: (a) a conductive powder of gold (Au), silver (Ag), nickel (Ni) or copper (Cu) particle, said powder preferably having an average particle size of up to 10 μm; (b) a thermosetting oligomer, typically an acrylic oligomer having an average molecular weight of from 500 to 1500; (c) an initiator for thermosetting; (d) a binder; and (e) a solvent.

There remains a need in the art to further develop compositions which can effective deposit a metallic network in ohmic contact with a substrate such that the contacting network will be characterized by a high conductivity—whereby resistive losses are minimized—and a low contact resistance with the substrate. The achievement of this need should not require the tolerance of reduced adhesion of the metallic network to the substrate, of diminished mechanical stability of the product or the bleeding of the binder resin onto the substrate when overlaid.

### STATEMENT OF THE INVENTION

In accordance with a first aspect of the invention there is provided an electrically conductive composition for use in the preparation of an electrically conductive network, said composition comprising, based on the total weight of the composition:
a) from 75 to 98 wt. % of a silver powder having a tap density of at least 4.0 g/cm³ and a specific surface area of less than 1.5 m²/g;
b) from 1 to 10 wt. % of a binder resin;
c) from 0 to 5 wt. % of a hardener; and,
d) from 0 to 10 wt. % of solvent,
   wherein said composition is characterized in that, when heated to a temperature at which the silver powder starts to sinter, the binder resin is not yet in a fully cured or fully dried state.

The curing or drying properties of the binder resin ensure that it is not in a set state at the onset of silver particle sintering. For example, curing of the binder resin may not have commenced at the onset of silver particle sintering or the binder resin may be in a partially cured or a partially dried state at the onset of silver particle sintering. Without being bound by theory, the mass mobility—that is the atomic diffusion and consolidation—of the silver particles during sintering within an uncured or not fully dried resin matrix leads to the development of a silver microstructure which is substantially uniform. Thereby the conductive feature formed of the sintered silver is characterized by a low electrical bulk resistivity.

The silver powder present in the composition may be characterized by at least one of: i) a mass median diameter particle diameter (D50) of from 0.5 to 6.0 μm, preferably from 0.8 to 5.0 μm, more preferably from 1.0 to 5.0 μm, more preferably from 1.1 to 4.0 μm, and even more preferably from 1.1 to 3.0 μm; ii) a D(10) of from 0.2 μm to 1.8 μm, preferably from 0.4 to 1.8 μm, more preferably from 0.4 to 1.7 μm and even more preferably from 0.6 to 1.7 μm; iii) a specific surface area of less than 1.0 m²/g, preferably less than 0.7 m²/g; and, iv) a tap density of from 4.0 to 8.0 g/cm³, and preferably from 4.8 to 6.5 g/cm³. For completeness, it is re-iterated here that these characterizing parameters of the silver powder are not mutually exclusive. The powder may be characterized by one, two, three or four of the stated parameters. Moreover, the powder may be defined by the broadest range of one parameter and the preferred range of a second parameter.

In an important embodiment, the binder resin of the electrically conductive composition comprises a hydrogenated aromatic epoxy resin, a cycloaliphatic epoxy resin or a mixture thereof. In particular, the binder resin may comprise an epoxy resin selected from the group consisting of: 1,2-cyclohexanedicarboxylic acid diglycidyl ester; bis(4-hydroxycylohexyl)methanediglycidyl ether; 4-methylhexahydrophthalic acid diglycidyl ester; 2,2-bis(4-hydroxycyclohexyl)propane diglycidyl ether; 3,4-epoxycyclohexylmethyl-3′, 4′-epoxycylohexane carboxylate; bis(3,4-epoxycyclohexylmethyl)adipate and, mixtures thereof.

It is noted that the advantageous properties of a binder resin comprising a hydrogenated aromatic epoxy resin, a cycloaliphatic epoxy resin or a mixture thereof may be enhanced by further including in said binder resin an epoxy resin selected from the group consisting of: urethane-modified epoxy resins; isocyanate-modified epoxy resins; epoxy ester resins; aromatic epoxy resins; and, mixtures thereof.

In accordance with a second aspect of the present invention, there is provided a method of forming a conductive network for a solar cell, said method comprising the steps of:
i) providing a substrate;
ii) forming a transparent conductive oxide film on said substrate;
iii) depositing onto the transparent conductive oxide an electrically conductive composition containing a silver powder as defined hereinbefore and in the appended claims; and,
iv) heating said electrically conductive composition at a temperature of from 100° to 250° C. for sufficient time to both sinter the silver powder contained in said composition and to fully cure or dry said composition.

In an embodiment, this method is used to form a conductive network for a hetero-junction solar cell and is characterized by the inclusion of a further step: v) disposing at least one metallic layer on said cured or dried composition, wherein the or each metallic layer comprises a metal independently selected from the group consisting of: tin; lead; copper; silver; nickel; tantalum; and, mixtures or alloys thereof.

The electrically conductive composition may preferably be deposited onto said transparent conductive oxide by a method selected from the group consisting of: screen printing; dispenser printing; ink jet printing; stencil printing; rotary screen printing; flexographic printing; gravure printing; and, spin coating. Using said methods or otherwise, the electrically conductive composition may be deposited in one or more lines having a width of from 20 to 70 μm. Additionally or alternatively, the electrically conductive composition may be deposited at a thickness of from 1 to 50 μm.

The conductive feature formed from the sintered silver in the above defined methods shows a beneficial, low electrical contact resistance to known transparent conductive oxides. Moreover, the cured composition shows strong adhesion to the transparent conductive oxides, as demonstrated by the peel strength test results obtained.

It is envisaged that the electrically conductive compositions may have utility beyond the fabrication of solar cells. As such, in accordance with a third aspect of the present invention, there is provided a method of forming a conductive network to bond at least one die to a substrate, said method comprising the steps of:
i) providing a substrate;
ii) applying the conductive composition as defined in any one of claims 1 to 10 onto the substrate;
iii) placing a die on said composition so that said composition is sandwiched between the substrate and the die; and,
iv) heating said electrically conductive composition at a temperature of from 100° to 250° C. for sufficient time to both sinter the silver powder contained in said composition and to fully cure or dry said composition.

### BRIEF DESCRIPTION OF THE DRAWINGS

FIG. 1 is a generalized schematic cross-sectional view of a heterojunction (HJ) solar cell.
FIG. 2 is a structure for screen printing conductive tracks on a wafer.

### DEFINITIONS

As used herein, the singular forms “a”, “an” and “the” include plural referents unless the context clearly dictates otherwise.

The terms “comprising”, “comprises” and “comprised of” as used herein are synonymous with “including”, “includes”, “containing” or “contains”, and are inclusive or open-ended and do not exclude additional, non-recited members, elements or method steps.

When amounts, concentrations, dimensions and other parameters are expressed in the form of a range, a preferable range, an upper limit value, a lower limit value or preferable upper and limit values, it should be considered understood that any ranges obtainable by combining any upper limit or preferable value with any lower limit or preferable value are also specifically disclosed, irrespective of whether the obtained ranges are clearly mentioned in the context.

As used herein, the term “sintering” is a method for making objects from particles or powder by heating the material—below its melting point—until its particles adhere and/or fuse to each other. “Sinterable” refers to materials that can be sintered. “Sintered” refers to particles or powder that have undergone a sintering process. A sintered mass refers to the formed shape that is the result of the sintering of powders or particulate. In the sintered mass, formerly discrete particles or powder grains retain a core, and the interstitial area from one core to another core is at least partially filled with a grain boundary layer that separates the cores.

As used herein, the fine, sinterable silver powder can be a pure silver powder, a metal particle coated with silver on its surface, or a mixture thereof. The fine, sinterable silver powder can be a commercially available product or may be prepared methods known in the art, such as mechanical milling, reduction, electrolysis and vapor phase processes.

Where a metal particle coated with silver on its surface is used as at least a portion of the sinterable silver powder, the core of the particle may be constituted by copper, iron, zinc, titanium, cobalt, chromium, tin, manganese or nickel or alloys of two or more of said metals, and the coating of silver should constitute at least 5 wt. %, preferably at least 20 wt. % and more preferably at least 40 wt. % based on the weight of the particle. Such a silver coating may be formed by electroless Ag-plating, electroplating or vapor deposition, as is known in the art.

Subject to meeting the defined parameters of particle size, surface area and tap density, there is no intention to limit the actual physical shape of the silver particles within the powder. Said particles may be, for instance, spheres, flakes, leaf-like particles, dendritic particles or combinations thereof. A preference for flakes and spheres might be mentioned.

The sinterable silver powder of the present invention is characterized by having a polydisperse particle population: it is a population of particles in which there is a range of particle sizes. The silver powders have thus been defined by specific “D-values” which herein provides a “mass division diameter”: it is the diameter which, when all particles in a sample are arranged in order of ascending mass, divides the sample's mass into specified percentages. The percentage mass of particles below the diameter of interest is the number expressed after the “D”. For example, the D10 diameter is the diameter at which 10% of a sample's mass is comprised of smaller particles, and D50 (mass median diameter) is the diameter at which 50% of a sample's mass is comprised of smaller particles. The maximum diameter is the maximum value in the particle diameter distribution and herein designated as D100.

In some applications of the present invention, the maximum particle diameter (D100) of the sinterable silver powder is not critical. However, it is noted that the sinterable silver powder will generally have a maximum particle diameter (D100) of less than 75 μm, for example less than 60 μm, less than 50 μm, less than 30 μm, or of less than 25 μm, for example less than 10 μm or less than 7.5 μm. Alternatively or additionally, the sinterable silver powder may have a D90 diameter of less than 7 μm, for example less than 6 μm or less than 5.5 μm.

The D10, D50 (mass median diameter), D90 and D100 particle sizes may be obtained using conventional light scattering techniques and equipment, such as: Hydro 2000 MU, available from: Malvern Instruments, Ltd., Worcestershire, United Kingdom; or Sympatec Helos, Clausthal-Zellerfeld, Germany.

The “tap density” of the particles recited herein is determined in accordance International Organization for Standardization (ISO) Standard ISO 3953. The principle of the method specified is tapping a specified amount of powder in a container—typically a 25 cm³ graduated glass cylinder—by means of a tapping apparatus until no further decrease in the volume of the powder takes place. The mass of the powder divided by its volume after the test gives its tap density.

As used herein, the term “specific surface area” refers to the surface area per unit mass of the particles concerned. As is known in the art, the Brunauer, Emmett, and Teller (BET) method may be employed to measure the specific surface area of said particles, which method include the steps of flowing gas over a sample, cooling the sample, and subsequently measuring the volume of gas adsorbed onto the surface of the sample at specific pressures.

For completeness, commercially available silver powders suitable for inclusion in the present invention include but are not limited to: FA-SAB-534, available from Dowa; P554-19, P620-22, P698-1, F741-6, F747-3 and F781-1, available from Metalor; and, SF134, available from Ames-Goldsmith.

Where the viscosity of the electrically conductive composition is mentioned, this viscosity has been measured at 25° C., unless otherwise stated, employing a TA Instruments Rheometer using either: i) 2 cm plate, 500 micron gap and shear rates of 1.5 s⁻¹ and 15 s⁻¹; or, ii) 2 cm plate, 200 micron gap and shear rates as indicated below (10 s⁻¹ and 100 s⁻¹).

Where the Volume Resistivity (VR) of the cured or dried electrically conductive composition is given herein, this parameter may be determined in accordance with the following protocol: i) samples of the composition were prepared for the compositions on glass plates at a wet thickness of approximately 40 μm and a sample length of more than 5.4 cm; ii) the samples were cured and dried according to the requirement for the binder resin used; iii) the glass plates were cooled to room temperature before measurement of sample thickness using a Mutitoyo Gauge and sample width using a back-light microscope; iv) Resistance (R) was measured by using Keithley 4 point probes over a 5.4 cm sample length; and, v) Volume Resistivity was calculated from the equation VR=(width of the sample (cm)×thickness of the sample (cm)×Resistance (Ohm))/length of the sample (cm). In the Examples herein below, Volume Resistivity (VR) is an average of three duplicate measurements each made in accordance with this protocol.

As used herein to describe components of the binder resin, “thermoplastic” is differentiated from “thermosetting” and refers to a resin which softens and melts when exposed to heat and re-solidifies to an often brittle and glassy state when cooled sufficiently. On the other hand, a thermosetting polymer irreversibly solidifies when heated. Thermosetting resins materials are typically resins that attain this set or solid state through being “dried” under the action of heat, through being “cured” via a chemical reaction requiring a curing agent, or through curing under irradiation.

As used herein, a “die” is a singular, semi-conductive element disposed on a semiconductor wafer and generally separated from its neighboring die(s) by scribe lines. After semiconductor wafer fabrication steps are completed, the die are generally separated into elements or units by a die singulation process, such as sawing.

### DETAILED DESCRIPTION OF THE INVENTION

The binder resin of the present invention commonly contains a thermosetting resin. Typically, such a thermosetting resin will be selected from the group consisting of: epoxy resin; oxetane resins; oxazoline resins; benzoxazine; resole; maleimides; cyanate esters; acrylate resins; methacrylate resins; maleates; fumarates; itaconates; vinyl esters; vinyl ethers; cyanoacrylates; styrenics; and, combinations thereof. Preferably, the thermosetting resin comprises one or more of: an epoxy resin; an acrylate resin; and, a methacrylate resin. In particular, the thermosetting resin comprises an epoxy resin.

Where applicable, certain of these thermosetting resins may require a hardener or (reactive) curing agent in order to cure. The choice of hardener or curing agent is not particularly limited, except that it must comprise functional groups suitable for reacting with the functional groups on the thermosetting resins in order to affect cross-linking. Determination of a suitable curing agent is within the general skill set and knowledge of a skilled person and should require no further elucidation here.

In an embodiment, wherein the electrically conductive composition is a die attach paste, the hardener is present in the composition from 2.5 to 3.75 wt. % based on the total weight of the composition. Anhydride based hardener is particularly preferred, in particular dodecenylsuccinic anhydride and methylhexahydrophthalicacid anhydride.

The applicant has found out that use of an anhydride based hardener, especially in a die attach paste compositions will decrease the viscosity of the composition and increase the adhesion of the composition. Furthermore, the applicant has found out that the use of anhydride based hardener provides additional cure shrinkage, and therefore, the silver particles are located closer to each other in the cured product, and therefore, better performance can be achieved.

An epoxy resin is any compound containing at least one or more reactive oxirane groups, referred to herein as “epoxy group(s)” or “epoxy functionality”. Epoxy resins as used herein may include mono-functional epoxy resins, multi- or poly-functional epoxy resins, and combinations thereof. The epoxy resins may be pure compounds but equally may be mixtures epoxy functional compounds, including mixtures of compounds having different numbers of epoxy groups per molecule. An epoxy resin may be saturated or unsaturated, aliphatic, cycloaliphatic, aromatic or heterocyclic and may be substituted. Further, the epoxy resin may also be monomeric or polymeric.

Suitable polymeric epoxies for use in the present invention include but are not limited to: linear polymers having terminal epoxy groups, for example a diglycidyl ether of a polyoxyalkylene glycol; polymer skeletal oxirane units, for example polybutadiene polyepoxide; and, polymers having pendant epoxy groups, for example a glycidyl methacrylate polymer or copolymer.

In an embodiment, the binder resin of the composition comprises an epoxy resin selected from the group consisting of: cycloaliphatic epoxy resins; cycloaliphatic epoxy resins modified with glycols; hydrogenated aromatic epoxy resins; epoxy phenolic novolac resins and cresol novolac type epoxy resins; bisphenol A-based epoxy resins; bisphenol F-based epoxy resins; and, mixtures thereof.

A cycloaliphatic epoxy resin according to the present invention is a hydrocarbon compound containing at least one non-aryl hydrocarbon ring structure and containing one, two or more epoxy groups. The cycloaliphatic epoxy compound may include an epoxy group fused to the ring structure and/or an epoxy group residing on an aliphatic substituent of the ring structure. It is preferred herein that the cycloaliphatic epoxy resin has at least one epoxy group residing on an aliphatic substituent of the ring. And suitable cycloaliphatic epoxy resins are described inter alia in: U.S. Pat. Nos. 2,750,395; 2,890,194; 3,318,822; and, 3,686,359.

In an important embodiment of the invention, the binder resin of the composition may comprise a hydrogenated aromatic epoxy resin, a cycloaliphatic epoxy resin or a mixture thereof. In particular, the binder resin may comprise an epoxy resin selected from the group consisting of: 1,2-cyclohexanedicarboxylic acid diglycidyl ester; bis(4-hydroxycylohexyl)methanediglycidyl ether; 4-methylhexahydrophthalic acid diglycidyl ester; 2,2-bis(4-hydroxycyclohexyl)propane diglycidyl ether; 3,4-epoxycyclohexylmethyl-3′, 4′-epoxycylohexane carboxylate; bis(3,4-epoxycyclohexylmethyl)adipate; and, mixtures thereof. Good results have, in particular, been obtained where the cycloaliphatic epoxy resins include: 1,2-cyclohexanedicarboxylic acid diglycidyl ester; 2,2-bis(4-hydroxycyclohexyl)propane diglycidyl ether; or, mixtures thereof.

In an interesting embodiment of the invention, the binder resin comprises: i) a hydrogenated aromatic epoxy resin and/or a cycloaliphatic epoxy resin as described above; and, ii) a further epoxy resin selected from the group consisting of: urethane-modified epoxy resins; isocyanate-modified epoxy resins; epoxy ester resins; aromatic epoxy resins; and, mixtures thereof. For example, the binder may comprise: i) from 40 to 100 wt. %, preferably from 50 to 90 wt. %, based on the total weight of binder resin, of said cycloaliphatic resin and/or hydrogenated aromatic epoxy resin; and, ii) from 0 to 60 wt. %, preferably from 10 to 50 wt. % of said further epoxy resin. A particular binder resin may, for example, have from 55 to 65 wt. % of a cycloaliphatic resin and from 35 to 45 wt. of a further, modified urethane or isocyanate epoxy resin.

In an embodiment directed to a die attach paste, the binder resin comprises mixture of epoxy resin and flex epoxy resin. Especially combination of epoxy resin, flexible epoxy resin and anhydride based hardener in the composition will promote to decrease the stress after the cure, and therefore, to improve the reliability of the cured product.

By the term “flexible epoxy” resin it is meant herein an epoxy compound, which has long alkyl chain as illustrated by the formula (1) below.

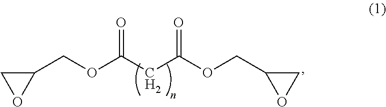

wherein n is greater than 20, preferably 26.

It is noted that isocyanate modified epoxy resins can have oxazolidine functionality if the isocyanate reacts directly with the epoxy, or ureido functionality if the isocyanate reacts with secondary hydroxyl groups present in the epoxy molecule. Commercial examples of isocyanate- or urethane-modified epoxy resins useful as second or further epoxy resins in the compositions of the present disclosure include: EPU-17T-6, EPU-78-11, and EPU-1761, available from Adeka Co.; DER 6508, available from Dow Chemical Co.; and, AER 4152, available from Asahi Denka.

The electrically conductive composition of the present invention comprises from 0 to 10 wt. %, for example from 0 or 0.1 to 8 wt. %, based on the total weight of the composition, of solvent. Broadly, suitable solvents for use in the present invention may be selected from the group consisting of: alcohols including high boiling point alcohols; aromatic hydrocarbons; saturated hydrocarbons; chlorinated hydrocarbons; ethers including glycol ethers; polyols; esters including dibasic esters and acetates; kerosene; ketones; amides; heteroaromatic compounds; and, mixtures thereof.

It is preferred that the solvent has a high boiling point, such that it does not evaporate during the disposition of the composition—from a printer, for example. As used herein, “high boiling point solvent” means a solvent having a boiling point of at least 115° C. at 1 atmosphere pressure. For completeness, such high boiling point solvents should also have a melting point of less than 25° C. to facilitate their use in printing. High boiling point solvents are commercially available or may be made by (re-) distilling a commercially-obtained solvent preparation.

In an embodiment, said high boiling point solvents are selected from the group consisting of: dipropylene glycol; ethylene glycol, diethylene glycol, triethylene glycol, hexylene glycol, 1-methoxy-2-propanol, diacetone alcohol, 2-ethyl-1,3-hexanediol, tridecanol, 1,2-octanediol, butyldiglycol, alpha-terpineol or beta-terpineol, 2-(2-butoxyethoxy)ethyl acetate, 2,2,4-trimetyl-1,3-pentanediol diisobutyrate, 1,2-propylene carbonate, carbitol acetate, butyl carbitol acetate, butyl carbitol, ethyl carbitol acetate, 2-phenoxy ethanol, hexylene glycol, dibutylphthalate, dibasic ester (DBE), dibasic ester 9 (DBE-9), dibasic ester 7 (DBE-7), and mixtures thereof. Good results have, in particular, been obtained where the solvent is selected from the group consisting of: carbitol acetate; butyl carbitol acetate; dibasic ester (DBE); dibasic ester 9 (DBE-9); dibasic ester 7 (DBE-7); and, mixtures thereof.

It can be advantageous for the binder resins of the present invention to contain thermoplastic resin in an amount up to 4 wt. %, for example an amount of from 0.1 to 3.0 wt. %, based on the total weight of the composition. Such thermoplastic resins can serve to limit the bleed of the resin, enhance the peel strength of the cured or dried composition when overlaid with a metallic layer, and optimize the electrical contact resistance to transparent conductive oxides on which the composition is disposed when constructing electrodes.

Suitable thermoplastic polymers include, but are not limited to: polyesters; phenoxy resins; phenolic resins; polysiloxane polymers; polystyrene copolymers; polyvinyl polymers; divinylbenzene copolymers; polyetheramides; polyvinyl acetals; polyvinyl butyrals; polyvinyl alcohols; polyvinyl acetates; polyvinyl chlorides; methylene polyvinyl ethers; cellulose esters in particular cellulose acetates including cellulose acetate butyrate; styrene acrylonitriles; amorphous polyolefins; thermoplastic urethanes; polyacrylonitriles; ethylene vinyl acetate copolymers and terpolymers; functional ethylene vinyl acetates; ethylene acrylate copolymers and terpolymers; ethylene- and styrene-butadiene copolymers. In an embodiment of the conductive composition, the thermoplastic polymer is selected from the group consisting of: polyester; phenoxy resins; and, cellulose acetates.

The electrically conductive composition of the present invention may further include compatible additives and modifiers which serve to stabilize the composition and/or to control the composition's rheology, substrate adhesion and appearance. Additives and modifiers may also be needed to maintain the desired contact angle between the electrically conductive composition and the substrate. Thereby, a non-exhaustive list of additives and modifiers for use in the present invention includes: thickeners; viscosity modifiers; rheology modifiers; wetting agents; leveling agents; adhesion promoters; de-foaming agents; electrical conductivity promoters; and, thermal conductivity promoters.

Whilst additives and modifiers will typically be included in toto in an amount up to 10 wt. %, for example from 0.01 to 5 wt. %, based on the total weight of the composition, it will be recognized that the most apt amount of additive or modifier may be varied to compensate for the different surface energies of substrates, the different adhesion properties of substrates, the requirements of different printing or application methods, and the heating strategy used to sinter the silver particles into metal conductors.

In a particular embodiment, the electrically conductive composition comprises from 0.01 to 1 wt. % of rheology modifier. The inclusion of such a modifier should serve to optimize the aspect ratio of the applied composition and, more particularly, to achieve an aspect ratio of ≥0.3, where said aspect ratio is defined as the ratio of the applied (printed) height of the composition to the applied (printed) line width of the composition. Suitable rheology modifiers may be associative or non-associative. And examples of suitable modifiers include: cellulosic materials, such as carboxymethylcelluose (CMC), hydroxyethylcellulose (HEC), methylcellulose (methocel, or MC), methyl hydroxyethyl cellulose (MHEC), and methyl hydroxypropyl cellulose (MHPC); colloidal silicas; metal organic gellants based, for example, on either aluminate, titanate, or zirconate; natural gums, such as alginate, carrageean, guar, and/or xanthan gums; organo-clays, such as attapulgite, bentonite, hectorite, and montmorrillonite; organo-waxes, such as castor oil derivatives (HCO-Wax) and/or polyamide-based organowaxes; polysaccharide derivatives; and, starch derivatives. A commercial example of a suitable rheology modifier is Crayvallac® Super available from Arkema Inc.

The electrically conductive composition is formed by combining the silver particles, the binder resin, any solvent or hardener required and any additives. The composition may be agitated during mixing of its components and/or subjected to a milling process after its formation in order to prevent or break up any particle aggregations. The selection of solvents and other liquid vehicles, and the particle loading should serve to provide a composition having a viscosity suitable for application by printing using, for instance, gravure printing, impression printing, flexographic printing, offset printing and the like. The skilled practitioner will be able to optimize the viscosity of the composition for specific printing methods.

To form the conductive features—that is a trace, contact, wire, electrode, line or other feature having electrical conductivity—the electrically conductive composition is deposited onto a substrate. Techniques such as dispensing and printing can facilitate the application of the composition to a specific locus on the substrate. It is envisaged that the present composition can be applied to conventional high temperature substrates such as glass, silicon, silicon oxides, cadmium telluride, copper indium gallium selenide and gallium arsenide. The application to low temperature substrates such as paper or polymer substrates is also not precluded. However, the electrically conductive compositions of the present invention find particular utility in forming conductive features on transparent conductive oxide (TCO) films on photovoltaic cells and, for the proposed die attach application, on metallic substrates.

After deposition, the composition described herein can be consolidated to form a mechanically cohesive and electrically conductive structure. The methods used for achieving consolidation of the deposited composition can include but are not limited to: a conventional heating furnace; infra-red irradiation; laser; microwave radiation; and, any other photonic radiation. The conductive composition on the substrate is heated to temperatures of from 100° to 250° C. in an appropriate atmosphere, which atmosphere is determined largely by the binder resin composition: the atmosphere may be reducing, oxygen-containing or inert. Moreover, the heating can be conducted with or without the application of pressure; in the former embodiment a pressure of from 1 to 5 atm. may be typical. The conductive composition is heated at the recited temperature for a sufficient time to permit the sintering of the silver particles to form the conductive feature and to cure or dry the binder resin. Without intention to limit the present invention, illustrative heating times at the stated temperature are from 10 to 120 minutes and 15 to 60 minutes.

Upon completion of sintering and drying I curing, the sintered product may be cooled either in the same atmosphere used for sintering or in some other atmosphere as might be required to maintain the resin matrix. The sintering and cooling atmospheres should have no significant deleterious effect on the cured or dried composite.

In some implementations, the electrically conductive composition is curable to form a film with a volume resistivity of less than 20 μΩ·cm, for example less than 10 μΩ·cm or less than 5 μΩ·cm. Furthermore, the film may be substantially free of imperfections, such as pin holes.

### Methods of Forming a Conductive Network for a Solar Cell

As mentioned above, the present invention also provides a method of forming a conductive network for a solar cell, said method comprising the steps of: i) providing a substrate; ii) forming a transparent conductive oxide film on said substrate; ii) depositing onto the transparent conductive oxide an electrically conductive composition containing a silver powder as defined hereinbefore; and, iv) heating said electrically conductive composition at a temperature of from 100° to 250° C. for sufficient time to both sinter the silver powder contained in said composition and to fully cure or dry said composition. This aspect of the present invention will now be illustrated with specific reference to a hetero-junction (HJ) solar cell and with reference to the appended drawing in which:

FIG. 1 is a generalized schematic cross-sectional view of a heterojunction (HJ) solar cell (100).

It will however be understood that this method is applicable to alternative solar cells as known in the art, containing for instance a different substrate composition and specific configuration.

The solar cell (100) of FIG. 1 comprises an n-type or p-type crystalline silicon (c-Si) layer (110), which may be a silicon wafer sliced from a mono- or poly-crystalline silicon ingot and will typically have a thickness of 20 to 300 μm. A first amorphous silicon (a-Si) layer (120) and a second amorphous silicon layer (121) are disposed on the c-Si layer (110). A first highly-doped p+ or n+ silicon layer (130) is then disposed on the first a-Si layer (120). Correspondingly, a second highly-doped n+ or p+ silicon layer (131) is disposed on the second a-Si layer (121). A first transparent conductive oxide (TCO) layer (140) is in turn disposed on the first p+/n+ layer (130) and a second transparent conductive oxide layer (141) is disposed on the second n+/p+ layer (131).

Front contact structures (150) and back contact structures (151) are disposed respectively on the first and second transparent conductive oxide layers (140, 141). The front (150) and back (151) contact structures are disposed discontinuously—as a network—so as to provide an ohmic contact with the transparent conductive oxide layers (140, 141) while still allowing incident radiation to reach the underlying silicon layers of the heterojunction solar cell (100). The front (150) and back (151) contact structures are here depicted as being constituted by a plurality of metallic layers of which the innermost layers (150a, 151a) comprise silver (Ag). To benefit from its advantageous properties, these silver layers (150a, 151a) are here derived from the electrically conductive composition of the present invention.

The transparent conductive oxide (TCO) layers (140, 141) may be composed of materials known in the art for this purpose, including but not limited to: indium tin oxide (ITO); indium zinc oxide; indium tungsten oxide; zinc oxide; zinc oxide doped with aluminium or boron; cadmium stannate; tin oxide; and, fluorine-doped tin-oxide. Such layers can be applied—at a layer thickness of up to 1000 nm, for example from 50 to 500 nm—by methods known in the field, of which methods might be mentioned Metal Organic Chemical Vapour Deposition (MOCVD), sputtering, Atmospheric Pressure Chemical Vapour Deposition (APCVD), Plasma-Enhanced Chemical Vapour Deposition (PECVD), spray pyrolysis, physical vapour deposition, electro-deposition, screen binding, and sol-gel processes.

In accordance with the present invention, electrically conductive composition containing a silver powder, as defined hereinbefore, is deposited onto a first transparent conductive layer (140, 141) and then heated at a temperature of from 100° to 250° C. for sufficient time to both sinter the silver powder contained in said composition and to fully cure or dry said composition. By virtue of the properties of the binder resin in said composition, the silver particles sinter prior to the complete drying or curing of that binder.

Without intention to limit the present invention, the electrically conductive composition is preferably deposited onto said transparent conductive oxide by a method selected from the group consisting of: screen printing; dispenser printing; ink jet printing; stencil printing; rotary screen printing; flexographic printing; gravure printing; and, spin coating. Such methods can allow for precise disposition of the layers (150a, 151a) which might be characterized by having a width of from 20 to 70 μm and a thickness of from 1 to 50 μm.

Optionally, these layers (150a, 151a) of composition may be overlain by a second layer which also comprises sinterable silver particles. A secondary print may be performed over the layers (150a, 151a) of either an electrically conductive composition in accordance with the present invention or of a distinct electrically conductive composition which contains sinterable silver particles but which does not meet the characteristics of the present invention. Where Ag is mentioned in the sequences of the following paragraph, this means either a singular silver layer (150a, 151a) or a bilayer (Ag-Ag) formed by such a double-printing operation.

The front (150) and—in the case of a bifacial cell—the back (151) structures of the hetero-junction solar cell (100) may then be further developed by disposing at least one metallic layer on said cured or dried composition, wherein the or each metallic layer comprises a metal independently selected from the group consisting of: tin; lead; copper; silver; nickel; tantalum; and, mixtures or alloys thereof. The front (150) and back (151) structures may include 1 to 4 further layers and might therefore be of the following illustrative forms: Ag—Ni—Cu—Sn; Ag—Ni—Cu—Sn—Ta; Ag—Ni—Cu—Ta—Sn; or Ag—Ta. Other constitutions and orders of the metallic layers are envisaged but, in these illustrative forms, the nickel and tantalum will layer over the Ag layer (150a, 151a) and can be disposed in this position by plating of the metals using the Ag layer as a seed.

### Method of Forming a Conductive Network Comprising at Least One Die

The electrically conductive composition of the present invention may also find utility as a “die-attach paste”, especially in high power die attach applications where high thermal conductivity—or low thermal resistivity—and thus good heat distribution is required. The paste serves to attach—or mechanically bond—the semiconductor die to an appropriate substrate but, upon sintering of the constituent silver particles, also forms a metallurgical bond between electrical terminals on the die and corresponding electrical terminals on the substrate. These sinterable die-attach pastes are stable in that they do not change or re-melt during subsequent thermal processing, such as the attachment of the element to a circuit board. Moreover, the composition can also be applied at the wafer level prior to the singulation of the individual die.

Typically, a drop of the electrically conductive composition is dispensed on the substrate and the die placed on top of it so that the composition is sandwiched between the substrate and the die, thereby forming a die/substrate package. The die is contacted to the composition with a sufficient degree of pressure and/or heat so that the composition spreads and completely covers the substrate under the die. It is desirable that the composition further forms a fillet, that is, a raised rim or ridge, at the periphery of the die. A skilled practitioner can determine the appropriate amount of electrically conductive composition, heat and pressure to apply so that the resultant die-attach fillet is of an appropriate size. It will be recognized that an excess of die-attach fillet will result in the die-attach contamination of the die surface and an insufficient die-attach fillet may result in subsequent die lifting or die cracking.

When so disposed between the substrate and the die, the electrically conductive composition needs to be heated for a sufficient time to both sinter the silver powder contained in said composition and to fully cure or dry said composition. Typically, the die/substrate package is fed on a belt through a furnace: the package may pass through a plurality of different temperature zones of incrementally increasing temperature up until a final zone having a temperature of, ideally, from 100° to 250° C. The ramp rate—the rate at which the temperature of the package is elevated as it travels on the belt—is selected to control both the evaporation of any volatiles in the electrically conductive composition and the commencement of sintering prior to the complete curing of the binder resin therein. Further, it is important that the evaporation of volatiles and rate of curing of the binder resin does not lead to the formation of any voids in the final adhesive layer. Without intention to limit the present invention, a ramp rate of from 30° to 60° C./minute may be suitable. Independently, a 15 to 90 minute residence time of the package in the final zone of the furnace may be appropriate.

It is considered that the sintering of the silver particles of the inventive composition whilst the binder resin is not yet fully cured or dried can obviate the formation of cracks in the adhesive bond.

### Illustrative Embodiment of the Present Invention

Without intention to limit the present invention, it is noted that good results have been obtained where the electrically conductive composition comprises:
a) from 75 to 98 wt. %, based on the total weight of the composition, of a silver powder having a maximum particle diameter (D100) of at most 55 μm, preferably at most 30 μm and more preferably at most 10 μm, a mass median diameter (D50) of from 0.5 to 6.0 μm, preferably from 0.8 to 5.0 μm, more preferably from 1.0 to 5.0 μm, more preferably from 1.1 to 4.0 μm, and even more preferably from 1.1 to 3.0 μm, a specific surface area of less than 1.0 m²/g and a tap density of from 4.0 to 6.5 g/m³;
b) from 1 to 10 wt. %, of a binder resin, wherein said binder resin comprises an hydrogenated aromatic epoxy resin, a cycloaliphatic epoxy resin or a mixture thereof;
c) from 0 to 5 wt. % of a hardener; and,
d) from 0.1 to 10 wt. % or from 0.1 to 8 wt. % of solvent, wherein said solvent preferably comprises or consists of high boiling point solvent.

Various features and embodiments of the disclosure are described in the following examples, which are intended to be representative and not limiting.

### EXAMPLES

Materials: The following materials were employed in the Examples:

| | |
|---|---|
| Epalloy 5200 | Epoxy resin available from CVC Chemicals |
| EPU 17 T-6 | Epoxy resin available from Adeka Corporation |
| Epiclon 830S | Epoxy resin available from Dainippon Ink & |
| | Chemicals, Inc |
| Epiclon 830S | Epoxy resin available from Dainippon Ink & |
| | Chemicals, Inc |
| Erisys GE-11 | Epoxy resin available from CVC Chemicals |
| Rhodorsil 2074 | Iodonium borate salt photoinitator available from |
| | Rhodia Inc. |
| CAA | Carbamic acid amide (N,N′-(4-methyl-1,3- |
| | phenylene)bis-1-pyrrolidinecarboxamide), |
| | available from Chemical Inc. |
| DDSA | Dodecenylsuccinic anhydride from available from |
| | Vertellus |
| Rikacid MH-700 | Methylhexahydrophthalic cid anhydride |
| | *4-MHHPA available from New Japan Chemical |
| Curezol 2 MA OK | Imidazole based hardener available from Air |
| | Products |
| 24-422A | Flexible epoxy resin having a long aliphatic |
| | chain - formula (1) wherein n is 26 - from Henkel |
| TC-505C | Silver powder available from Tokuriki Technical |
| Curezol 2PHZ-S | Imidazole based hardener available from Shikoku |
| | Chemicals Corporation |
| CA | Carbitol Acetate solvent, available from Acros |
| | Chemicals |
| Propylene carbonate | solvent, available from Acros Chemicals |
| Butyl carbitol acetate | solvent, available from Acros Chemicals |
| PKHJ | Thermoplastic phenoxy resin available from |
| | Inchem Corporation |
| CAB 381-2 | Thermoplastic cellulose ester resin available |
| | from Eastman Chemical Co. |
| Crayvallac ® Super | Rheology modifier available from Arkema Inc. |
| SF134 | Silver powder available from Ames Goldsmith |
| FA-SAB-534 | Silver powder available from Dowa |
| AG-SAB-499 | Silver powder available from Dowa |
| P620-22 | Silver Powder available from Metalor |
| P698-1 | Silver Powder available from Metalor |
| P741-6 | Silver Powder available from Metalor |
| P781-1 | Silver Powder available from Metalor |
| P718-21 | Silver Powder available from Metalor |
| Vylon-226 | Polyesters resin available from TOYOBO |
| Bluesil PI 2074 | Hardener available from Bluestar Silicones |
| | International |

### Examples 1-9

To form the electrically conductive compositions described in Table 1 herein below, the silver particles, the epoxy resin(s), thermoplastic resins, solvents, hardener and any additives were simply mixed under sufficient agitation to prevent observable silver particle aggregations. The compositional values given in Table 1 are wt. %, based on the total weight of the composition. The formed compositions were then evaluated in accordance with the viscosity and volume resistivity test methods mentioned herein before and further using the following methods.

Electrical Contact Resistance (CR): This was determined by printing the electrically conductive composition in a Transfer Length Measurement (TLM) structure on a textured crystalline silicon (c-Si) wafer coated with indium tin oxide (ITO). The principle of this method is outlined in Tuttle, Contact Resistance and TLM Measurements, Iowa State University Dept. of Electrical and Computer Engineering, http://tuttle.merc.iastate.edu/ee432/topics/metals/tlm_measurements.pdf. A TLM structure was obtained using 5 strips with dimensions of 12 mm ×1 mm wherein the strips exhibited an increasing distance between the strips going from 0.125 mm to 2 mm: the pitches between the strips were respectively 0.125 mm, 0.25 mm, 0.5 mm, 1 mm and 2 mm. The resistance between the neighboring contact strips was measured by a Keithley multimeter and plotted as a function of the distance. The wafers are isolated by a laser etch.

Peel strength: Using a stencil, 1.2 mm wide tracks of said composition were printed on a textured TCO (ITO) coated c-Si wafer and subsequently dried/cured for 20 minutes at 20° C. After being held for 1 hour at 25° C., the printed height of the cured/composition was measured. Thereafter a SnPb or SnPbAg coated Cu ribbon with a width of 1.2 mm was dipped into a flux (Henkel X33-08i), dried using hot air for a timed period of 50 seconds and then soldered to the dried ink strip. The soldering conditions included back heating at 50° C., a solder set temperature of 360° C. and a soldering tip temperature of c. 225° C. After completion of soldering, the sample was rested for 1 hour at 25° C. before commencing the peel. Using a peel speed of 8.8 mm/s, the ribbon was peeled off under an angle of 180°; the force needed for this was recorded.

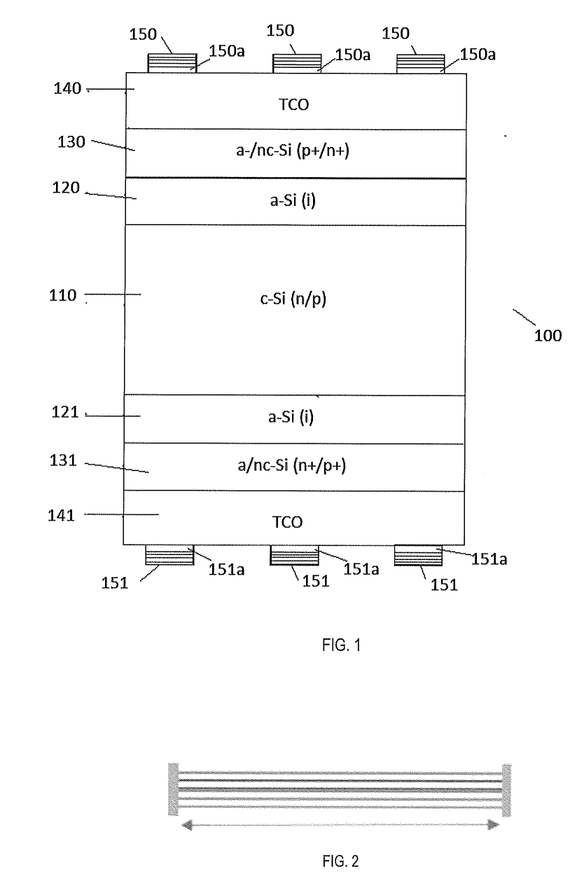

Line resistance: is determined in accordance with the following protocol: i) samples of the composition were prepared for the composition on a textured ITO coated crystalline silicon wafer by screen printing conductive tracks through a screen with emulsion openings of 55 micron wide and about 5 cm long in a structure as shown in FIG. 2; ii) the silicon wafers were cured and dried according the requirement for the composition; iii) wafers were cooled to room temperature before measurement of resistance using a Keithley 4 point probes over the full sample length (distance between the two bars as indicated by arrow in picture); Line resistance is calculated from equation below: LR (ohm/cm)=Resistance (ohm)×number of lines (5 in example above)/length of printed sample (cm).

TABLE 1

| Component | Ex. 1 | Ex. 2 | Ex. 3 | Ex. 4 | Ex. 5 | Ex. 6 | Ex. 7 | Ex. 8 | Ex. 9 |
|---|---|---|---|---|---|---|---|---|---|
| Epalloy 5200 | 2.87 | 3.197 | 3.197 | 3.197 | 4.00 | 3.91 | 2.35 | 2.906 | 2.921 |
| EPU 17 T-6 | 1.91 | 2.131 | 2.131 | 2.131 | | | 1.56 | 1.938 | 1.947 |
| Rhodorsil 2074 | 0.05 | | | | | | | | |
| Rhodorsil 2074/PPC | | 0.107 | 0.107 | 0.107 | | | | 0.097 | 0.097 |
| (50:50) | | | | | | | | | |
| CAA | | | | | | 0.59 | 0.59 | | |
| CA | 3.38 | 5.870 | 5.870 | 5.870 | 5.00 | 3.50 | 3.50 | 4.546 | 4.076 |
| PKHJ | | 1.739 | 1.739 | 1.739 | | | | 1.581 | 1.589 |
| CAB 381-2 | | | | | 0.50 | | | | |
| CAB 381-2/CA (30/70) | | | | | | 1.60 | 1.60 | | |
| Crayvallac ® Super | | | | | 0.50 | | | | |
| FA-SAB-534 | 91.79 | 86.957 | | | | 95.00 | 95.00 | | |
| P741-6 | | | 86.957 | | | | | | |
| P781-1 | | | | 86.957 | | | | | |
| P554-19 | | | | | 90.00 | | | | |
| P698-1 | | | | | | | | 88.932 | |
| SF134 | | | | | | | | | 89.37 |
| Tests | | | | | | | | | |
| Viscosity at 1.5 s⁻¹ shear | 508.0 | 183 | 107 | 103 | | 400 | 421 | 155.5 | 155.8 |
| (Pa · s) | | | | | | | | | |
| Viscosity at 15 s⁻¹ shear | 58.4 | 36 | 31 | 35 | | 59 | 62 | 52.5 | 52.5 |
| (Pa · s) | | | | | | | | | |
| Viscosity at 10 s⁻¹ shear | | | | | 81.64 | | | | |
| (Pa · s) | | | | | | | | | |
| Viscosity at 100 s⁻¹ shear | | | | | 21.09 | | | | |
| (Pa · s) | | | | | | | | | |
| Thixotropic Index (T.I.) | 8.7 | 5.1 | 3.5 | 3.0 | 3.9 | 6.8 | 6.8 | 3.0 | 3.0 |
| Volume Resistivity | 7.2 | 8.5 | 9.3 | 8.2 | 6.2 | 5.4 | 5.7 | 7.1 | 7.8 |
| (μΩ · cm) | | | | | | | | | |
| Contact Resistance | 7.9 | | | | | | | 11.2 | 1.2 |
| (mΩ · cm²) | | | | | | | | | |
| Peel Strength (N/mm) | 0.2 | 0.3 | 0.5 | 0.2 | | | | 0.9 | 0.5 |

In addition to the measured parameters, the electrically conductive compositions of these Examples showed no observable resin bleeding onto the indium tin oxide layer.

### Examples 10-12

To form the electrically conductive compositions described in Table 2 herein below, the components were simply mixed under sufficient agitation to prevent observable silver particle aggregations. The compositional values given in Table 2 are wt. %, based on the total weight of the composition. The formed compositions were then evaluated in accordance with the viscosity and volume resistivity test methods mentioned herein before and further using the following methods.

Die Shear Strength (DSS): Samples of each composition were disposed to a thickness of 75 microns between a 3×3 mm silver die and each of a cleaned and uncleaned copper coated DBC (direct bond copper) substrate; any cleaning of the DBC was performed in accordance with the standard IPC-TM-650. The temperature of each die substrate package was then raised from 25° C. to 200° C. over a period of approximately 1 hour before being held at 200° C. for a 20 minute period to cure the composition. Each sample was cooled to room temperature and was then tested for die shear strength; each test was conducted at least twice per sample. The results were collated and averaged and the die shear strength reported in Table 2.

Thermal conductivity: Samples of the composition were disposed in a Teflon mold having a width of 3 mm and depth (thickness) of 0.7 mm. The temperature of the composition was then raised from 25° C. to 200° C. over a period of approximately 1 hour before being held at 200° C. for a 20 minute period to cure the composition and thereby form thermal diffusivity pellets. The thermal conductivity of said pellets was then determined via laser flash in accordance with the test method specified in ASTM E 1461.

TABLE 2

| | Ex. 10 | Ex. 11 | Ex. 12 |
|---|---|---|---|
| Component | | | |
| Epalloy 5200 | 4.948 | 4.936 | 4.936 |
| Rhodorsil 2074 | 0.049 | | |
| CAA | | 0.296 | 0.296 |
| CA | 2.969 | 2.962 | 2.962 |
| P741-6 | 92.034 | 91.807 | 87.216 |
| P620-22 | | | 4.590 |
| Tests | | | |
| Silver content (%, liquid) | 92.0 | 91.8 | 91.8 |
| Silver content (%, cured) | 94.8 | 94.6 | 94.6 |
| Viscosity at 15 s⁻¹ shear (Pa · s) | 26 | 24 | 23 |
| Volume Resistivity (μΩ · cm) | 5.6 | 5.2 | 6.1 |
| Thermal Conductivity (W/mK) | 110-114 | 121-145 | 118-151 |
| DSS (kg mm) - DBC not cleaned | 2.2 | 1.7 | 1.9 |
| DSS (kg mm) - DBC cleaned | 2.5 | 2.0 | 2.1 |

In view of the foregoing description and examples, it will be apparent to those skilled in the art that equivalent modifications thereof can be made without departing from the scope of the claims.

### Examples 13-16

To form the electrically conductive compositions described in Table 3 herein below, the components were simply mixed under sufficient agitation to prevent observable silver particle aggregations. The compositional values given in Table 3 are wt. %, based on the total weight of the composition. The formed compositions were then evaluated in accordance with the viscosity and volume resistivity test methods mentioned herein before and further using the following methods.

Die Shear Strength (DSS): Samples of each composition were dispensed at the Ag or Cu substrate firstly, and the 2*2 mm Ag plated die were mounted at the top of the sample. Controlled the bondline thickness around 25 um. The temperature of each die substrate package was then raised from 25° C. to 200° C. over a period of approximately 1 hour before being held at 200° C. for a 60 minute period to cure the composition. Each sample was cooled to room temperature and was then tested for die shear strength; each test was conducted at least twice per sample. The results were collated and averaged and the die shear strength reported in Table 3.

TABLE 3

| | Ex. 13 | Ex. 14 | Ex. 15 | Ex. 16 |
|---|---|---|---|---|
| Component | | | | |
| DDSA | 3.36 | 3.36 | | |
| Rikacid MH-700 | | | | 3.36 |
| 2MAOK | | | 0.08 | |
| Epalloy 5200 | 1.94 | 3.64 | 3.8 | 1.94 |
| 24-422A | 1.7 | | 3.8 | 1.7 |
| TC-505C | 90.6 | 90.6 | 90.6 | 90.6 |
| CA | 2.4 | 2.4 | 2.4 | 2.4 |
| Tests | | | | |
| Silver content (%, liquid) | 90.6 | 90.6 | 90.6 | 90.6 |
| Silver content (%, cured) | 92.8 | 92.8 | 92.8 | 92.8 |
| Viscosity at 19 s⁻¹ shear (Pa · s) | 8.5 | 9 | 40.2 | 9 |
| Volume Resistivity (μΩ · cm) | 7.5 | 7.0 | 55 | 6.5 |
| Thermal Conductivity (W/mK) | 84-108 | 90-115 | 10-20 | 93-118 |
| DSS @ 260 deg C. (kg mm) - Ag | 1.3 | 1.4 | 0.45 | 1.4 |
| substrate | | | | |
| DSS @ 260 deg C. (kg mm) - Cu | 1.1 | 0.5 | 0.3 | 0.6 |
| substrate | | | | |

### Examples 17-21

To form the electrically conductive compositions described in Table 4 herein below, the components were simply mixed under sufficient agitation to prevent observable silver particle aggregations. The compositional values given in Table 4 are wt. %, based on the total weight of the composition. The formed compositions were then evaluated in accordance with the viscosity and volume resistivity test methods mentioned herein before and further using the following methods.

TABLE 4

| | Ex. 17 | Ex. 18 | Ex. 19 | Ex. 20 | Ex. 21 |
|---|---|---|---|---|---|
| Component | | | | | |
| Epiclon 830S | | 2.05 | | | 2.00 |
| Epalloy 5200 | 2.08 | 1.52 | 2.82 | 2.44 | |
| Erisys GE-11 | | | | | 1.00 |
| PKHJ | 1.22 | | 1.66 | 1.43 | |
| EPU17T-J | 1.39 | | 1.88 | 1.63 | |
| Ag-SAB-499 | 91.38 | 92.4 | | | 46.00 |
| Ag-SAB-573 | | | 26.38 | | |
| Ag-SAB-583 | | | | 44.76 | |
| P718-21 | | | | 44.76 | 46.00 |
| Ag-SAB-136 | | | 61.56 | | |
| Bluesil PI 2074 | 0.17 | 0.41 | 0.24 | 0.205 | 0.4 |
| CA | 3.59 | | 4.19 | 4.57 | |
| Vylon-226 | | 1.03 | | | 1.00 |
| Butyl carbitol acetate | | 2.57 | | | 3.00 |
| Propylene carbonate | 0.17 | | 0.24 | 0.205 | |
| Tests | | | | | |
| Viscosity at 1.5 s⁻¹ shear (Pa · s) | | | 400.7 | 436.4 | |
| Viscosity at 15 s⁻¹ shear (Pa · s) | | | 65.3 | 72.2 | |
| T.I. | | | 6.1 | 6.0 | |
| Volume Resistivity (μΩ · cm) | 4.7E−6 | 3.5E−6 | 6.8-7.4E−6 | 6.5E−6 | 5.5E−6 |
| Line resistance (ohm/cm) | 0.45 (55) | 0.42 (55) | 0.75 (55) | 0.7 (55) | 0.72 (55) |
| (opening in micron) | | | | | |
| Contact resistance (mohm · cm²) | 4.1 | 2.0 | 3.5 | 2.6 | 1.9 |
| Peel strength (N/mm) | | | 1.7 | 1.4 | 1.0 |

What is claimed is:

1. An electrically conductive composition for use in the preparation of an electrically conductive network, said composition comprising, based on the total weight of the composition:
a) from 75 to 98 wt. % of a silver powder having a tap density of at least 4.0 g/cm³ and a specific surface area of less than 1.5 m²/g;
b) from 1 to 10 wt. % of a binder resin;
c) from 0 to 5 wt. % of a hardener; and,
d) from 0 to 10 wt. % of solvent,
wherein said composition is characterized in that, when heated to a temperature at which the silver powder starts to sinter, the binder resin is not yet fully cured or fully dried.

2. The electrically conductive composition according to claim 1, wherein the silver powder has a mass median diameter (D50) of from 0.5 to 6.0 μm, preferably from 0.8 to 5.0 μm, more preferably from 1.0 to 5.0 μm, more preferably from 1.1 to 4.0 μm, and even more preferably from 1.1 to 3.0 μm.

3. The electrically conductive composition according to claim 1, wherein the D(10) of the silver powder is from 0.2 μm to 1.8 μm, preferably from 0.4 to 1.8 μm, more preferably from 0.4 to 1.7 μm and even more preferably from 0.6 to 1.7 μm.

4. The electrically conductive composition according to claim 1, wherein the specific surface area of the silver powder is less than 1.0 m²/g, preferably less than 0.7 m²/g.

5. The electrically conductive composition according to claim 1, wherein the silver powder has a tap density of from 4.0 to 8.0 g/cm³, and preferably from 4.8 to 6.5 g/cm³.

6. The electrically conductive composition according to claim 1, wherein the binder resin comprises a hydrogenated aromatic epoxy resin, a cycloaliphatic epoxy resin or a mixture thereof.

7. The electrically conductive composition according to claim 6, wherein the binder resin comprises an epoxy resin selected from the group consisting of: 1,2-cyclohexanedicarboxylic acid diglycidyl ester; bis(4-hydroxycylohexyl)methanediglycidyl ether; 4-methylhexahydrophthalic acid diglycidyl ester; 2,2-bis(4-hydroxycyclohexyl) propane diglycidyl ether; 3,4-epoxycyclohexylmethyl-3′,4′-epoxycylohexane carboxylate; bis(3,4-epoxycyclohexylmethyl)adipate and, mixtures thereof.

8. The electrically conductive composition according to claim 6, wherein the binder resin further comprises an epoxy resin selected from the group consisting of: urethane-modified epoxy resins; isocyanate-modified epoxy resins; epoxy ester resins; aromatic epoxy resins; and, mixtures thereof.

9. The electrically conductive composition according to claim 1 comprising:
a) from 75 to 98 wt. %, based on the total weight of the composition, of a silver powder having a maximum particle diameter (D100) of at most 55 μm, preferably at most 30 μm and more preferably at most 10 μm, a mass median diameter (D50) of 0.5 to 6.0 μm, preferably from 0.8 to 5.0 μm, more preferably from 1.0 to 5.0 μm, more preferably from 1.1 to 4.0 μm, and even more preferably from 1.1 to 3.0 μm, a specific surface area of less than 1.0 m²/g and a tap density of from 4.0 to 6.5 g/m³;
b) from 1 to 10 wt. %, of a binder resin, wherein said binder resin comprises an hydrogenated aromatic epoxy resin, a cycloaliphatic epoxy resin or a mixture thereof;
c) from 0 to 5 wt. % of a hardener; and,
d) from 0.1 to 8 wt. % of solvent, wherein said solvent preferably comprises or consists of high boiling point solvent.

10. The electrically conductive composition according to claim 1 comprising a thermoplastic resin in an amount up to 4 wt. %, preferably in an amount of from 0.1 to 3.0 wt. %, based on the total weight of the composition.

11. A method of forming a conductive network for a solar cell, said method comprising the steps of:
i) providing a substrate;
ii) forming a transparent conductive oxide film on said substrate;
iii) depositing onto the transparent conductive oxide an electrically conductive composition, containing a silver powder as defined in claim 1; and,
iv) heating said electrically conductive composition at a temperature of from 100° to 250° C. for sufficient time to both sinter the silver powder contained in said composition and to fully cure or dry said composition.

12. The method according to claim 11, wherein the electrically conductive composition is deposited onto said transparent conductive oxide by a method selected from the group consisting of: screen printing; dispenser printing; ink jet printing; stencil printing; rotary screen printing; flexographic printing; gravure printing; and, spin coating.

13. The method according to claim 11, wherein the electrically conductive composition is deposited in one or more lines having a width of from 20 to 70 μm.

14. The method according to claim 11, wherein the electrically conductive composition is deposited at a thickness of from 1 to 50 μm.

15. The method according to claim 11 for forming a conductive network for a hetero-junction solar cell, said method further comprising the step of:
v) disposing at least one metallic layer on said cured or dried composition, wherein the or each metallic layer comprises a metal independently selected from the group consisting of: tin; lead; copper; silver; nickel; tantalum; and, mixtures or alloys thereof.

16. A method of forming a conductive network comprising at least one die, said method comprising the steps of:
i) providing a substrate;
ii) applying the conductive composition as defined in claim 1 onto the substrate;
iii) placing a die on said composition so that said composition is sandwiched between the substrate and the die; and,
iv) heating said electrically conductive composition at a temperature of from 100° to 250° C. for sufficient time to both sinter the silver powder contained in said composition and to fully cure or dry said composition.
